(19) United States
(12) Patent Application Publication
(10) Pub. No.: US 2003/0037723 A9
(43) Pub. Date: Feb. 27, 2003

(54) High throughput epitaxial growth by chemical vapor deposition

(75) Inventors: Srikanth Kommu, St. Peters, MO (US); Gregory M. Wilson, Chesterfield, MO (US)

Correspondence Address: SENNIGER POWERS LEAVITT AND ROEDEL, ONE METROPOLITAN SQUARE, 16TH FLOOR, ST LOUIS, MO, 63102, US

(73) Assignee: MEMC Electronic Materials, Inc.

(21) Appl. No.: 10/001,716

(22) Filed: Nov. 15, 2001

Related U.S. Application Data
(60) Provisional application No. 60/249,854, filed on Nov. 17, 2000.

(51) Int. Cl. C30B 23/00; C30B 25/00; C30B 28/12; C30B 28/14; C30B 1/00; H01L 21/20; H01L 21/36; C23C 16/00

(52) U.S. Cl. 117/93; 118/728; 117/105

(57) ABSTRACT

A method and apparatus for the high throughput epitaxial growth of a layer on the surface of a substrate by chemical vapor deposition is provided. In one embodiment, the method of the present invention comprises placing the substrate within a reactor vessel and passing a horizontal flow of reactant gas comprising a precursor chemical through the reactor vessel. The flow of the reactant gas is defined as having a Reynolds number of at least about 5000. The substrate is heated to a temperature sufficient to thermally decompose the precursor chemical and deposit an epitaxial layer on the substrate. In accordance with a preferred embodiment of the present invention, the substrate is placed within the reactor vessel at a position such that the flow of the reactant gas is characterized as a fully developed turbulent flow.

### CROSS-REFERENCE TO RELATED APPLICATIONS

This application claims the benefit of U.S. Provisional Application Serial No. 60/249,854 filed Nov. 17, 2000, the entire disclosure of which is hereby incorporated herein by reference.

### BACKGROUND OF THE INVENTION

The present invention relates generally to methods and apparatus for the epitaxial growth of a layer on the surface of a substrate by chemical vapor deposition, more particularly high throughput methods and apparatus for the epitaxial growth of silicon on the surface of a semiconductor wafer.

Epitaxial growth by chemical vapor deposition (CVD) is a process which uses chemically reactive gases to deposit thin solid layers on the surface of a substrate. CVD is a dynamic process involving complex chemical reactions for the simultaneous transport of mass, momentum and energy. Hence, the quality of the deposited layers is determined by the interactions of various transport phenomena and the reaction kinetics in the CVD reactor apparatus, which in turn depend on process conditions such as flow rates, gas velocities, pressure, temperature, concentration of chemical species, reactor geometry, etc.

CVD is used throughout industry, for example, in the production of microelectronics, magnetic materials, optical devices, automobiles and ceramics. In the silicon-based semiconductor industry, CVD is used to deposit a wide variety of films including polycrystalline silicon (polysilicon), epitaxial silicon, silicon oxides and silicon nitrides on the surface of semiconductor wafers. An advantage of the CVD process as compared to other deposition processes such as evaporation, sputtering, etc. is that it is capable of producing thin films of a wide variety of materials with precisely defined and highly reproducible electrical, optical, chemical and mechanical properties.

Many types of CVD reactors may be used depending on the range of operating conditions required for the purpose and function of the epitaxial layer to be grown. For example, CVD reactors may comprise horizontal flow reactors, vertical flow reactors, pancake reactors, barrel reactors, continuous belt reactors, etc. However, horizontal flow reactors capable of producing high quality epitaxial layers on large diameter substrates are increasingly used in the silicon industry for the production of single crystal silicon wafers.

Horizontal flow CVD reactors for the epitaxial growth of single crystal silicon have conventionally been operated at very low reactant gas velocities and correspondingly low Reynolds (Re) numbers (e.g., Re from 20 to 150). As described in U.S. Pat. No. 5,944,904, the reasoning behind operating at low gas velocities is to ensure a laminar flow of reactant gas across the surface of the substrate upon which the epitaxial layer is deposited. Laminar flow is desired because it is easier to control and inhibits the unwanted deposition of polysilicon and/or particulate contamination from recirculating gas flows. However, operating at low reactant gas velocities and low Reynolds numbers results in reduced mass transfer coefficients and increased mass transfer boundary layers at the surface of the substrate resulting in an inefficient deposition process with lower throughput capabilities.

The silicon industry imposes stringent demands on the quality of epitaxial layers produced by the CVD process. For example, epitaxial layers on modem semiconductor wafers must meet increasingly stringent specifications regarding good thickness uniformity and minimum particulate generation. In addition, CVD film deposition techniques in the silicon industry must be economical, for example, by achieving a high deposition rate and a high reactor throughput. Thus, the increasing demand for silicon wafers creates an ever-present need to improve process design and operation for the rapid production of silicon wafers.

### SUMMARY OF THE INVENTION

Among the several objects of this invention, therefore, may be noted the provision of a method and apparatus for epitaxial growth on the surface of a substrate by chemical vapor deposition; the provision of such a method and apparatus for the epitaxial growth of single crystal silicon on a semiconductor wafer; the provision of such a method and apparatus wherein the time of transport of precursor chemical from the flow of reactant gas to the substrate surface is reduced to enable an increase in the epitaxial deposition rate and permit high throughput processing; the provision of such a method and apparatus which achieves excellent thickness uniformity in the deposited layer; the provision of such a method and apparatus which achieves minimal particulate contamination in the deposited layer; and the provision of such a method and apparatus that provides for the efficient use, reuse and recycle of reactants.

Briefly, therefore, the present invention is directed to a method for growing an epitaxial layer on the surface of a substrate by chemical vapor deposition. The method comprises placing the substrate on a susceptor within a reactor vessel comprising a wall member. The susceptor is positioned within the reactor vessel such that the substrate received on the susceptor is in spaced opposition to the wall member. A horizontal flow of reactant gas comprising a precursor chemical is passed through the reactor vessel between the wall member and the substrate received on the susceptor. The flow of the reactant gas between the wall member and the substrate has a Reynolds number of at least about 5000. The substrate is heated to a temperature sufficient to thermally decompose the precursor chemical and deposit an epitaxial layer on the substrate. In accordance with a preferred embodiment of the present invention, the substrate is placed within the reactor vessel at a position such that the flow of the reactant gas between the wall member and the substrate is characterized as a fully developed turbulent flow.

Other objects and features of this invention will be in part apparent and in part pointed out hereinafter.

### DETAILED DESCRIPTION OF THE PREFERRED EMBODIMENT

In accordance with the present invention, methods and apparatus have been discovered for epitaxial growth by CVD which can deposit an epitaxial layer having excellent thickness uniformity on the surface of a substrate at a high rate to enable high throughput processing with minimal particulate generation.

CVD processes include convective and diffusive transport of precursor chemicals from the reactant gas to the wafer surface within the reactor vessel; chemical reactions in the gas-phase leading to new reactive species and byproducts; convective and diffusive transport of the reactants and reaction products from the homogeneous reactions to the wafer surface; adsorption of these species on the wafer surface; surface diffusion of adsorbed species over the surface; heterogeneous surface reactions on the surface leading to the formation of a solid film; desorption of gaseous reaction products; and convective and diffusive transport of reaction products to the outlet of the reactor.

The present invention is primarily directed to high throughput, horizontal flow CVD reactors. Examples of conventional horizontal flow CVD reactors include the ASM Epsilon One single-wafer epitaxial reactor (commercially available from ASM International N.V. of Bilthoven, The Netherlands) and the EPI Centura single-wafer epitaxial reactor (commercially available from Applied Materials of Santa Clara, Calif.) Generally, such horizontal flow CVD reactors comprise a reactor vessel or chamber made from quartz or other suitable material and containing a graphite susceptor for receiving a substrate, a SiC ring surrounding the susceptor and, optionally, rotating means for supporting and rotating the susceptor. Such reactors further comprise multiple (e.g., three) inlets for introducing the flow of reactant gas into the quartz reactor vessel. In operation, the substrate received on the susceptor within the quartz reactor chamber is heated radiatively by lamp arrays placed outside the quartz reactor chamber such that the wafer is maintained at an essentially constant temperature (1125° C. is a typical wafer temperature suitable for epitaxial deposition). Reactant gas, generally comprising a precursor chemical and a carrier gas (e.g., hydrogen) is introduced into the reactor vessel through the gas inlets and flows over the surface of the substrate. The precursor chemical reacts within the reactor vessel to deposit the desired epitaxial layer on the surface of the substrate. The reactant and product gases then exit the reactor through the reactor vessel outlet. The exterior surfaces of the reactor are cooled throughout the process with recirculated air.

The epitaxial deposition process typically comprises two steps. In the first step, a substrate is loaded into the reactor vessel onto a susceptor, and the surface of the substrate is contacted with a cleaning gas such as hydrogen or a hydrogen/hydrochloric acid mixture at about 1150° C. to “pre-bake” the surface of the substrate. This “pre-bake” step cleans the surface of the substrate to allow the epitaxial layer to grow continuously and evenly. In the second step of the epitaxial deposition process, a chemically reactive precursor chemical is passed over the surface of the substrate as part of a reactant gas while the surface of the substrate is heated to a temperature of about 1100° C. or higher. The precursor chemical decomposes and reacts with the surface of the substrate to deposit and grow an epitaxial layer on the surface. During both steps of the epitaxial deposition process the substrate is supported in the reactor vessel by the susceptor, which is optionally rotated during the process to ensure even growth of the epitaxial layer. The susceptor is generally comprised of high purity graphite having a silicon carbide layer completely covering the graphite. The graphite is preferably covered by silicon carbide to reduce the amount of contaminants such as iron which may be released from the graphite during high temperature processing. Conventional susceptors used in epitaxial growth processes are well known in the art and described in U.S. Pat. Nos. 4,322,592, 4,496,609, 5,200,157, and 5,242,501.

For the deposition of silicon on a semiconductor wafer, the wafer surface is exposed to a reactant gas comprising a precursor chemical. The precursor chemical is passed across the wafer surface as part of the reactant gas, which preferably further comprises a carrier gas such as hydrogen. Suitable precursor chemicals include, for example, SiCl₄, SiH₃Cl, SiH₂Cl₂, SiHCl₃, SiH₄ and mixtures thereof. Most preferably, the source of silicon during the deposition is SiHCl₃ as it tends to be much cheaper than other silicon sources. In addition, epitaxial deposition using SiHCl₃ may be conducted at atmospheric pressure. This is advantageous because a vacuum pump is not required, which simplifies the construction of the reactor chamber. Moreover, operating at atmospheric pressure presents fewer safety hazards and lessens the chance of air leaking into the reactor chamber. Typically, the reactant gas comprises from about 70% to about 85% SiHCl₃ with the remainder comprising the carrier gas. As the concentration of the precursor chemical in the reactant gas increases, the amount of silicon available at the surface of the wafer increases, thereby increasing the epitaxial deposition rate. However, it should be understood that the increase in deposition rate due to increased concentration of the precursor chemical in the reactant gas is practically limited by the tendency for polysilicon deposition. Preferably, the concentration of SiHCl₃ and carrier gas in the reactant gas for high throughput processing is about 82% and about 18%, respectively.

In accordance with the present invention, it has been determined that an increased epitaxial deposition rate can be realized by increasing the reactant gas velocity across the surface of the wafer. Increasing the reactant gas velocity reduces the time-scale for transport of precursor chemical species to the wafer surface as compared to the time-scale for reaction with the surface. The increased mass transport of the precursor chemical to the wafer surface at increased reactant gas velocities is attributable to a thinning of the mass-transfer boundary layer at the wafer surface. Thus, it has been found that, for a typical SiHCl₃ reactant system in a horizontal flow CVD reactor, the epitaxial silicon deposition can be almost entirely kinetically controlled such that reaction kinetics determine the product composition, structure and deposition rate, especially at low and intermediate deposition temperatures. In the absence of mass transfer resistance, the intrinsic surface reaction kinetics will govern the silicon deposition rate at a fixed wafer temperature and at a given gas composition.

It is also important to note that variations in temperature at the wafer surface should be minimized in a kinetically controlled system. Because the surface reaction rates are very sensitive to temperature variations, the epitaxial deposition rate will vary significantly with temperature, resulting in thickness non-uniformity across the surface of the substrate. However, due to the recent advances in the state of Rapid Thermal Processing (RTP) technology, it is now possible to minimize temperature non-uniformities across the wafer surface so that kinetically controlled epitaxial deposition is possible.

The reaction kinetics of a typical SiHCl₃ system for the growth of single crystal silicon on a silicon wafer involve the transport of SiHCl₃ precursor chemical molecules from the gas phase to the surface of the silicon wafer. SiHCl₃ molecules then decompose at a certain rate according to the following reaction:

SiHCl₃(g)→SiCl₂*+HCl(g)

SiCl₂* is adsorbed at reactive sites on the wafer surface. The adsorbed SiCl₂* species is most likely bonded to the wafer surface with the two chlorine atoms pointing to the gas stream. Therefore, after adsorption one ends up with a silicon surface covered with chlorine atoms. This adsorbed surface reacts with hydrogen atoms in the reactant gas to reduce SiCl₂* to Si and release HCl gas according to the following reaction:

SiCl₂*+H₂(g)→Si(s)+2HCl(g)

Hence the overall silicon deposition rate is given by the following equation:

$${R}_{Si} = \frac{{K}_{ad} {C}_{SiHCl3}^{s}}{1 + \frac{{K}_{ad} {C}_{SiHCl3}^{s}}{{K}_{r} {C}_{H2}^{s}}} \qquad ( 31 )$$

where K_{ad} is the rate of adsorption reaction and Kᵣ is the rate of desorption reaction.

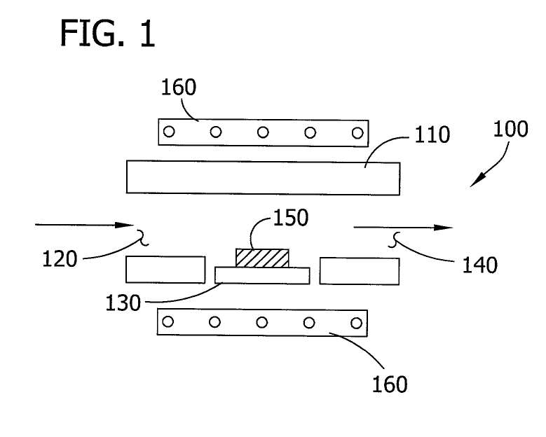

Referring to FIG. 1, the method of the present invention is conducted in a horizontal flow CVD reactor system including a reactor vessel 100 comprising a wall member 110, a single gas inlet 120 for introducing reactant gas, a susceptor 130 surrounded by a SiC ring (not shown) and a single gas outlet 140 for removing the flow of reactant gas from the vessel. A substrate 150 is placed on the susceptor 130 within the reactor vessel 100. Susceptor 130 is positioned within reactor vessel 100 such that substrate 150 received on the susceptor is in spaced opposition to wall member 110 to form a horizontal flow channel between the surface of the substrate and wall member 110 for the flow of reactant gas. Reactant gas comprising a precursor chemical and a carrier gas such as hydrogen is introduced at ambient temperature (e.g., about 25° C.) into reactor vessel 100 through single gas inlet 120.

The reactant gas introduced into the reactor vessel flows through the horizontal flow channel between wall member 110 and substrate 150 received on the susceptor 130. The wafer is heated radiatively by lamp arrays 160 placed outside the reactor vessel such that the wafer is maintained at a constant temperature. The precursor chemical reacts in the vessel depositing the desired solid silicon film on the surface of the heated wafer. The reactant and product gases leave the reactor through reactor outlet 140. The exterior surfaces of the reactor vessel are cooled with recirculated air.

Increasing the reactant gas velocity through the reactor vessel in accordance with the present invention results in an increase of the Reynolds number, which characterizes the flow of reactant gas in the horizontal flow channel. The dimensionless Reynolds number is used to partially characterize laminar and turbulent flows and is primarily a function of the velocity and kinematic viscosity of a particular flow. Laminar flow is generally smooth and steady while turbulent flow is fluctuating and agitated. For the flow of reactant gas in the horizontal flow channel, Reynolds number (Re_{D}) is defined according to the following equation:

Re_{D}=ρvD/μ

where ρ represents the density of the reactant gas, v represents the average velocity of the gas flow and μ is the viscosity of the reactant gas. D is hydraulic diameter, which in the present case is the reactor height or, more particularly, the distance between the wall member of the reactor vessel and the wafer received on the suceptor. In the practice of the present invention, the flow of reactant gas between the wall member and the substrate has a Reynolds number of at least about 2100. Reynolds numbers in excess of about 2100 are generally associated with turbulent flows. Contrary to prevailing practices in horizontal flow CVD reactor systems for the epitaxial deposition of silicon, it has been determined that operating at high Reynolds numbers for the flow of reactant gas (i.e., Reynolds numbers characteristic of turbulent flow) advantageously increases the deposition rate of single crystal silicon epitaxial layers exhibiting a high degree of thickness uniformity with minimal particulate generation. In order to achieve higher epitaxial deposition rates, shorten cycle time and increase throughput, the flow of reactant gas between the wall member and the substrate preferably has a Reynolds number of at least about 5000, and more preferably at least about 10,000 or even higher. Theoretically, there is no upper limit to the reactant gas velocity and Reynolds number for the flow of reactant gas between the wall member and the substrate. However, it should be understood that increased reactant gas velocities increase the pressure within the reaction vessel which places practical limits on the design of high throughput CVD reactor systems.

Although the calculated value for the Reynolds number of the reactant gas flow between the wall member and the surface of the substrate recieved on the susceptor may be in excess of 2100 and therefore indicative of turbulent flow, turbulent flow may not develop for some horizontal flow distance within the reactor. This entrance length, Lₑ, (i.e., the length required to achieve a fully developed turbulent flow) is correlated to the Reynolds number according to the following equation

Lₑ=4.4DRe_{D}^{1/6}

where D and Re_{D} are as defined above. It has been determined that advantageous results may be achieved by placing the substrate in the reactor vessel on the susceptor at a position within the entrance length, Lₑ, or downstream in the fully developed turbulent flow. In a preferred embodiment, the substrate is placed in the reactor vessel on the susceptor at a position downstream of the reactant gas inlet at a distance greater than Lₑ such that the flow of reactant gas between the wall member and the substrate is characterized as fully developed turbulent flow. Preferably, the reactor system is designed such that the Lₑ required for fully developed turbulent flow is less than about 1000 mm, more preferably less than about 500 mm, even more preferably less than about 200 mm. In some CVD systems, Lₑ required for fully developed turbulent flow may be prohibitive for the practical design of a high throughput CVD reactor. In such instances, it may be possible to reduce Lₑ by inducing disturbance in the flow of reactant gas upstream of the substrate, for example, by placing flow obstruction means in the flow of reactant gas upstream of the substrate with respect to the direction of gas flow through the reactor vessel. It is contemplated that such flow obstruction means may include baffles, weirs and wire meshes.

The high reactant gas velocities employed in accordance with the present invention may be achieved, at least in part, by reducing the reactor height (i.e., the horizontal flow channel), D, as defined above. By reducing this dimension of the reactor, the quantitative flow of the reactant gas is reduced resulting in a more economical system (e.g., lower reactant gas usage and lessened pump requirements). Preferably the reactor height of the high throughput CVD reactor is less than about 5 mm, more preferably no greater than about 2 mm.

It should be understood that the method of the present invention may be practiced in an existing CVD reactor system having a reactor height, D, not optimized for high throughput processing. Conventional horizontal flow CVD reactors typically have a reactor height of about 15 mm or more. In such applications, in order to minimize reactant gas losses, the precursor chemical passing through the reactor vessel in the reactant gas flow is recycled and reintroduced into the reactor vessel. Although particularly advantageous in reactor systems having a large flow height, recycling of the precursor chemical may be employed in any CVD system. Preferably, the recycled precursor chemical is purified prior to being reintroduced into the reactor vessel.

As described above, the demand for wafers having a large diameter (e.g., up to about 300 mm or more) which also satisfy rigorous industry specifications has been increasing in recent years. Because maintaining a large diameter wafer at a constant temperature is a concern at high temperatures of about 1100° C. to 1200° C., the method of the present invention is preferably practiced at more easily controlled lower deposition temperatures. Although lower temperature processing tends to decrease deposition rate, it has been found that the high reactant gas velocity used in accordance with the present invention provides high throughput while avoiding the difficulties associated with high deposition temperature. Preferably, the substrate is heated to a temperature of no greater than about 1100° C., more preferably no greater than about 1000° C.

Further, the process of the present invention may be practiced at a pressure of less than one atmosphere absolute.

During the deposition process the substrate may be rotated. However, in the practice of the present invention, it has been found that rotation of the substrate to obtain increased thickness uniformity may not be necessary and is avoided if possible to simplify the reactor design. Likewise, the use of a single gas inlet for introducing the reactant gas into the reactor vessel is also possible and simplifies the reactor design.

Further, it has been found that the process of the present invention results in minimal particulate generation. For example, without being held to a particular theory, it is believed that operating at increased reactant gas velocities characterized by a high Reynolds number reduces the number of buoyant recirculations, thereby reducing the amount of particle contamination at the surface of the substrate.

What is claimed:

1. A method for growing an epitaxial layer on the surface of a substrate by chemical vapor deposition, the method comprising:
placing the substrate on a susceptor within a reactor vessel comprising a wall member, and positioning the susceptor within the reactor vessel such that the substrate received on the susceptor is in spaced opposition to the wall member;
passing a horizontal flow of reactant gas comprising a precursor chemical through the reactor vessel between the wall member and the substrate received on the susceptor, the flow of the reactant gas between the wall member and the substrate having a Reynolds number of at least about 5000; and
heating the substrate to a temperature sufficient to thermally decompose the precursor chemical and deposit an epitaxial layer on the substrate.

2. The method as set forth in claim 1 wherein the substrate is placed within the reactor vessel at a position such that the flow of the reactant gas between the wall member and the substrate is characterized as a fully developed turbulent flow.

3. The method as set forth in claim 2 wherein the entrance length required for fully developed turbulent flow is less than about 1000 mm.

4. The method as set forth in claim 2 wherein the entrance length required for fully developed turbulent flow is reduced by inducing disturbance in the flow of reactant gas upstream of the substrate.

5. The method as set forth in claim 4 wherein disturbance in the flow of reactant gas is induced by placing flow obstruction means in the flow of reactant gas upstream of the substrate with respect to the direction of gas flow through the reactor vessel.

6. The method as set forth in claim 1 wherein the substrate comprises a silicon wafer.

7. The method as set forth in claim 1 wherein the precursor chemical is selected from the group consisting of SiH₄, SiH₃Cl, SiH₂Cl₂, SiHCl₃ and SiCl₄.

8. The method as set forth in claim 1 wherein the precursor chemical comprises SiHCl₃ and the reactant gas further comprises a carrier gas.

9. The method as set forth in claim 8 wherein the concentration of precursor chemical in the reactant gas is about 82%.

10. The method as set forth in claim 1 wherein the distance between the wall member and the substrate received on the susceptor is no greater than about 5 mm.

11. The method as set forth in claim 1 wherein the distance between the wall member and the substrate received on the susceptor is no greater than about 2 mm.

12. The method as set forth in claim 1 wherein the distance between the wall member and the substrate received on the susceptor is at least about 15 mm.

13. The method as set forth in claim 12 wherein precursor chemical passing through the reactor vessel is recycled.

14. The method as set forth in claim 13 wherein the recycled precursor chemical is purified before being reintroduced into the reactor vessel.

15. The method as set forth in claim 1 wherein the substrate is heated to a temperature of from about 1100° C. to about 1200° C.

16. The method as set forth in claim 1 wherein the substrate is heated to a temperature of no greater than about 1100° C.

17. The method as set forth in claim 1 wherein the substrate is heated to a temperature of no greater than about 1000° C.

18. The method as set forth in claim 1 wherein the pressure within the reactor vessel is less than 1 atmosphere absolute.

19. The method as set forth in claim 1 wherein the reactant gas is introduced into the reactor vessel at a single gas inlet.

20. The method as set forth in claim 1 wherein the substrate is rotated during deposition of the epitaxial layer on the substrate.

21. The method as set forth in claim 1 wherein the substrate is not rotated during deposition of the epitaxial layer on the substrate.
